(19) United States
(12) Patent Application Publication
(10) Pub. No.: US 2024/0367981 A1
(43) Pub. Date: Nov. 7, 2024

(54) METHOD FOR CONTINUOUS EPITAXY OF CARBON FILM

(71) Applicant: PEKING UNIVERSITY, Beijing (CN)

(72) Inventors: Kaihui LIU, Beijing (CN); Zhibin ZHANG, Beijing (CN); En'ge WANG, Beijing (CN)

(73) Assignee: PEKING UNIVERSITY, Beijing (CN)

(21) Appl. No.: 18/566,878

(22) PCT Filed: Nov. 1, 2022
(86) PCT No.: PCT/CN2022/128950

§ 371 Date: Dec. 4, 2023

(30) Foreign Application Priority Data
Nov. 9, 2021 (CN) 202111318030.3

(51) Int. Cl. C01B 32/205; C30B 1/02

(52) U.S. Cl. CPC C01B 32/205; C30B 1/02; C01P 2002/60; C01P 2004/01

(57) ABSTRACT

A method for continuous epitaxy of a carbon film, including the following steps: Si, providing a foil, wherein the foil is selected from a nickel foil or a copper-nickel alloy foil and has a first surface and a second surface; and S2, using the foil as a substrate and placing it on a solid carbon source, wherein the first surface of the foil is positioned close to the solid carbon source, while the second surface of the foil is positioned away from the solid carbon source, and then heating the foil and the solid carbon source, so that a carbon film is formed by continuous epitaxy on the second surface of the foil.

This application claims priority from Chinese Patent Application No. 202111318030.3 filed on Nov. 9, 2021, the disclosure of which is incorporated by reference herein in its entirety as part of this application.

### TECHNICAL FIELD

The present disclosure belongs to the field of materials, and relates to a method for infiltration growth of a carbon film which is induced by a solid carbon source and is not a vapor deposition process.

### BACKGROUND OF THE INVENTION

Carbon films are mostly prepared by physical vapor deposition or chemical vapor deposition, or by carbonization of polymer materials such as polyetherimide. Usually, carbon atoms in a carbon film are mainly in the form of SP² hybridization.

Graphene is a two-dimensional single atomic layer composed of SP² hybridized carbon atoms arranged in a honeycomb structure. Graphite is one of the most common forms of carbon materials, and can be considered to be composed of many layers of graphene stacked. Therefore, the mechanical, thermal, acoustic, electrical and other properties of graphite are highly anisotropic. On the horizontal plane of graphite, these properties are comparable to those of graphene, which also makes graphite widely used in thermal conductivity, electrical conductivity, fire resistance, batteries, lubrication, steelmaking, catalysis, etc.

However, for common graphite, there are many grain boundaries in the layer, which greatly reduce the excellent in-plane properties of graphite. Therefore, most of the excellent properties of graphene cannot be exerted on graphite. For example, highly oriented pyrolytic graphite (HOPG), which is commonly used in scientific research, has poor single crystallinity, and the size of a single domain is only on the scale of hundreds of microns. Therefore, the preparation of large-sized single-crystal graphite is an urgent problem that needs to be solved in the field of materials.

### SUMMARY OF THE INVENTION

The present disclosure provides a method for continuous epitaxy of a carbon film, which method comprises the following steps:
S1, providing a foil selected from a nickel foil or a copper-nickel alloy foil and having a first surface and a second surface; and
S2, using the foil as a substrate and placing it on a solid carbon source, wherein the first surface of the foil is positioned close to the solid carbon source, while the second surface of the foil is positioned away from the solid carbon source, and then heating the foil and the solid carbon source, thereby leading the carbon film to grow on the second surface of the foil through diffusion.

According to an embodiment, the foil is a single-crystal nickel foil.

According to an embodiment, heating of the foil and the solid carbon source is carried out in a tubular furnace.

According to an embodiment, heating of the foil and the solid carbon source is carried out under a protective gas, wherein the protective gas is selected from one or more of argon gas, nitrogen gas, and hydrogen gas. For example, the protective gas is a mixture of argon gas and hydrogen gas, preferably, wherein the flow rates of argon gas and hydrogen gas are 100-1000 sccm for Ar and 5-200 sccm for H₂, respectively.

According to an embodiment, heating of the foil and the solid carbon source includes the steps of: heating to a temperature of 900-1350° C. within 60-120 minutes and then maintaining at this temperature for 10 minutes to 50 hours.

According to an embodiment, after the growth is completed, the atmosphere is kept unchanged and the carbon film is naturally cooled down to room temperature.

According to an embodiment, step S1 includes the steps of: S11, placing a polycrystalline nickel foil on a high-temperature resistant substrate and pre-oxidizing at 150-650° C. for 1-5 h; S12, introducing an inert protective gas, and then heating to 1000-1350° C. within 60-120 minutes; S13, maintaining at 1000-1350° C. for 1-20 h to carry out an annealing process of the nickel foil; and S14, after the annealing, maintaining the atmosphere condition unchanged and cooling the system to room temperature to obtain the single-crystal nickel foil.

According to an embodiment, steps S11-S14 are carried out in a tubular furnace.

According to a preferred embodiment, the inert protective gas in step S12 is a mixture of Ar and H₂. According to a more preferred embodiment, the volume ratio of Ar to H₂ in step S12 is from 0.5:1 to 200:1. According to an even more preferred embodiment, the flow rates of Ar and H₂ in step S12 are 100-1000 sccm and 5-200 sccm, respectively.

According to an embodiment, in step S11, the high-temperature resistant substrate is a quartz or corundum substrate, and the tubular furnace is a quartz or corundum furnace. For example, the selection of high-temperature resistant substrate and tubular furnace in step S11 depends on an annealing temperature: when the annealing temperature is 1000-1150° C., quartz material is selected, and when the annealing temperature is 1150-1350° C., corundum material is selected.

According to an embodiment, the solid carbon source is selected from one or more of graphite paper, graphite powder, activated carbon and carbon black.

According to an embodiment, the carbon film obtained is single-crystal graphite or graphene. According to a preferred embodiment, the carbon film obtained is single-crystal graphite, with a size of 1 to 10 cm and a thickness of 0.1 to 50 μm.

According to an embodiment, the obtained single-crystal graphite has a consistent orientation.

### BRIEF DESCRIPTION OF THE DRAWINGS

In order to more clearly illustrate the technical solutions of the examples of the present disclosure, the drawings of the examples will be briefly introduced below. Apparently, the drawings in the following description only relate to some examples of the present disclosure and do not limit the present disclosure.

FIG. 1 is a schematic diagram of the process of growing single-crystal graphite using single-crystal nickel foil according to the present disclosure.

FIG. 2 is the optical photograph (a) and the electron back-scattered diffraction (EBSD) characterization result (b) of the single-crystal nickel foil prepared in Example 1 of the present disclosure.

FIG. 3 is a photograph of the single-crystal graphite prepared in Example 4 of the present disclosure.

FIG. 4 is an electron back-scattered diffraction pattern (EBSD) of highly oriented pyrolytic graphite (HOPG) and single-crystal graphite prepared in Example 4 of the present disclosure, wherein (a), (b) and (c) are the EBSD mapping of HOPG in the x direction, y direction, and z direction respectively; (d), (e) and (f) are the EBSD mapping of the single-crystal graphite prepared in Example 4 of the present disclosure in the x direction, y direction, and z direction respectively.

### DETAILED DESCRIPTION OF THE EMBODIMENTS

In order to make the purpose, technical solutions and advantages of the examples of the present disclosure more clear, the technical solutions of the examples of the present disclosure will be clearly and completely described below in conjunction with the drawings of the examples of the present disclosure. Apparently, the described examples are some, but not all, of the examples of the present disclosure. Based on the described examples of the present disclosure, all other examples obtained by those of ordinary skill in the art without creative efforts fall within the protection scope of the present disclosure.

The present disclosure may be embodied in other specific forms without departing from the essential attributes of the present disclosure. It should be understood that, without conflict, any and all embodiments of the present disclosure may be combined with technical features of another embodiment or other embodiments to obtain additional embodiments. The present disclosure includes additional embodiments resulting from such combinations.

All publications and patents mentioned in this disclosure are hereby incorporated by reference into the present disclosure in their entirety. To the extent that any usage or terminology used in any publications and patents incorporated by reference conflicts with the usage or terminology used in this disclosure, the usage or terminology used in this disclosure shall prevail.

The section headings used in this article are for the purpose of organizing the article only and should not be construed as limitations on the subject matter described.

Unless otherwise defined, all technical and scientific terms used herein have their ordinary meaning in the art to which the claimed subject matter belongs. If there are multiple definitions for a term, the definition herein shall prevail.

The use of similar words such as “include”, “contain” or “comprise” in this disclosure means that the elements appearing before the word encompass the elements and their equivalents listed after the word, without excluding unlisted elements. The term “include”, “contain” or “comprise” as used herein can be open, semi-closed and closed. In other words, the term also includes “consisting essentially of” or “consisting of”.

It should be understood that when used in this disclosure, a singular form (e.g., “a” or “an”) may include plural referents unless otherwise specified.

The reagents and raw materials used in the present disclosure are commercially available or can be prepared by conventional preparation methods.

Unless otherwise indicated, when a range of any type (e.g., thickness) is disclosed or claimed, it is intended to individually disclose or claim every possible value that the range could reasonably encompass, including any sub-ranges encompassed therein. For example, in the present disclosure, a numerical range of thickness such as 1 to 200 microns indicates a thickness within this range, where 1 to 200 microns should be understood to include 1, 2, 3, 4, 5, 6, 7, 8, 9, 10 . . . 200 microns and also include the ranges 1-5 and 1-10. Except in the working examples or otherwise indicated, all numbers expressing amounts of material, conditions of reaction, times of duration, and quantitative properties of material, etc. stated in the specification and claims should be understood as being modified in all instances by the term “about”. It should also be understood that any numerical range recited herein is intended to include all sub-ranges within that range and any combination of the individual endpoints of such ranges or sub-ranges.

In this application, solid carbon source refers to solid that provides carbon elements with a carbon purity of 90% or more, such as carbon fiber, graphite paper, graphite powder, activated carbon, and carbon black, etc. In an embodiment, the solid carbon source is selected from one or more of graphite paper, graphite powder, activated carbon and carbon black.

The continuous epitaxy in this application means that carbon atoms of a solid carbon source dissolve into a foil from one surface of the foil, diffuse through the foil, and precipitate on the other surface of the foil to form a carbon film.

The purity of raw materials of the nickel foil or copper-nickel alloy foil in this application is usually 99.5% or more. In an embodiment, the purity of raw materials of the nickel foil or copper-nickel alloy foil is 99.8% or more. In a preferred embodiment, the purity of raw materials of the nickel foil or copper-nickel alloy foil is 99.9% or more. In a more preferred embodiment, the purity of raw materials of the nickel foil or copper-nickel alloy foil is 99.99% or more.

Single-crystal nickel foil in this application means that its internal crystal lattice orientation and arrangement are completely consistent, and there is no grain boundary defect in the entire nickel foil.

Single-crystal graphite in this application means that its internal lattice orientation and arrangement are completely consistent, and there is no grain boundary defect in the entire graphite.

The present disclosure provides a method for continuous epitaxy of a carbon film, which method includes the following steps:
S1, providing a foil selected from a nickel foil or a copper-nickel alloy foil and having a first surface and a second surface; and
S2, using the foil as a substrate and placing it on a solid carbon source, wherein the first surface of the foil is positioned close to the solid carbon source, while the second surface of the foil is positioned away from the solid carbon source, and then heating the foil and the solid carbon source, thereby causing the carbon film to grow on the second surface of the foil through diffusion.

In the growth method of the present disclosure, the continuous epitaxy of a carbon film is achieved by utilizing absorption of carbon from a solid carbon source into a foil and then a solid-state diffusion transmission. It should be noted that the above method is different from a traditional vapor deposition method, and the growth of a carbon film is achieved in the absence of carbon-containing gases such as methane, ethylene, and acetylene.

In an embodiment, the solid carbon source is selected from one or more of graphite paper, graphite powder, activated carbon and carbon black.

In step S1, the foil is selected from a nickel foil or a copper-nickel alloy foil. The nickel foil can be polycrystalline nickel foil or single-crystal nickel foil. The copper-nickel alloy foil can be, for example, a foil with a copper-nickel alloy composition of 90/10 or 70/30. In a preferred embodiment, the foil is selected from single-crystal nickel foil.

In step S2, the foil and the solid carbon source are heated but below the temperature at which the foil melts, for example 100-400° C. below the melting temperature of the foil. Without being bound by any theory, it is believed that heating the foil and the solid carbon source causes carbon atoms to be adsorbed into the foil and “dissolved” in the foil, and thermal diffusion of carbon causes the carbon atoms to be precipitated and arranged on the other surface of the foil.

In an embodiment, heating of the foil and the solid carbon source in step S2 is carried out in a tubular furnace.

In a preferred embodiment, heating of the foil and the solid carbon source in step S2 is carried out under a protective gas, wherein the protective gas is selected from one or more of argon gas, nitrogen gas, and hydrogen gas. For example, the protective gas is selected from argon gas, nitrogen gas, hydrogen gas, argon and hydrogen gas, nitrogen and hydrogen gas, argon and nitrogen gas, or argon and nitrogen and hydrogen gas. In a more preferred embodiment, the protective gas is a mixture of argon gas and hydrogen gas. In an even more preferred embodiment, the flow rates of argon gas and hydrogen gas in the mixture are 100-1000 sccm and 5-200 sccm, respectively.

In an embodiment, heating the foil and the solid carbon source in step S2 includes the steps of: heating to a temperature of 900-1350° C. within 60-120 min, and then maintaining at this temperature for 10 min to 50 h. In a preferred embodiment, heating the foil and the solid carbon source in step S2 is heating nickel foil and the solid carbon source, which includes the following steps: heating to a temperature of 1000-1350° C. within 60-120 min, and then maintaining at this temperature for 10 min to 50 h. The longer the maintaining time, the thicker the carbon film obtained. The thickness of the foil is typically 1-200 microns. In some embodiments, the foil has a thickness of 10-120 microns, such as 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99, 100, 101, 102, 103, 104, 105, 106, 107, 108, 109, 110, 111, 112, 123, 114, 115, 116, 117, 118, 119 or 120 microns.

In an embodiment, after the continuous epitaxy in step S2 is completed, the atmosphere is kept unchanged and the system is naturally cooled to room temperature.

In a preferred embodiment, the foil in step S1 is a single-crystal nickel foil. As shown in FIG. 1, a single-crystal nickel foil having a first surface and a second surface is provided; the single-crystal nickel foil is used as a substrate and placed on a solid carbon source, wherein the first surface of the single-crystal nickel foil is positioned close to the solid carbon source, while the second surface of the single-crystal nickel foil is positioned away from the solid carbon source, and finally a high-quality single-crystal graphite is grown on the second surface of the single-crystal nickel foil.

For the preparation and characterization of single-crystal nickel foil, please refer to “Seeded growth of large single-crystal copper foils with high-index facets” in Nature, Volume 581, pages 406-410, 2020. For example, nickel foil (100 micron thick, 99.994%, Alfa Aesar) is first oxidized in air at 150-650° C. for 1-4 hours and then annealed in a reducing atmosphere at 1200° C. for 3-6 hours, and a single-crystal nickel foil with a dimension of about 5×5 cm² is obtained after thermal annealing. By repeating typical annealing procedures, several high-index single-crystal nickel foils can be produced. A single-crystal nickel foil can be characterized by X-ray diffraction (XRD) and electron back-scattered diffraction (EBSD).

In a preferred embodiment, providing a foil in step S1 is providing single-crystal nickel foil, which includes the following steps:
S11, placing a polycrystalline nickel foil on a high-temperature resistant substrate and pre-oxidizing at 150-650° C. for 1-5 h;
S12, introducing an inert protective gas, and then heating to 1000-1350° C. within 60-120 minutes;
S13, maintaining at 1000-1350° C. for 1-20 h to anneal the nickel foil; and
S14, after the annealing, maintaining the atmosphere condition unchanged and cooling the system to room temperature to obtain the single-crystal nickel foil.

In an embodiment, steps S11-S14 are carried out in a tubular furnace.

The pre-oxidizing in step S11 can be carried out under oxygen or air atmosphere.

In a preferred embodiment, the inert protective gas in step S12 is a mixture of nitrogen and H₂ or a mixture of Ar and H₂ or a mixture of nitrogen, Ar and H₂. In a more preferred embodiment, the inert protective gas in step S12 is a mixture of Ar and H₂. In an even more preferred embodiment, the inert protective gas in step S12 is a mixture of Ar and H₂, wherein the volume ratio of Ar to H₂ is from 0.5:1 to 200:1. In an even more preferred embodiment, the flow rates of Ar gas and H₂ gas in step S12 are 100-1000 sccm and 5-200 sccm, respectively.

The high-temperature resistant substrate in step S11 may be a quartz or corundum substrate, and the tubular furnace in steps S11-S14 may be a quartz or corundum furnace. For example, the selection of the high-temperature resistant substrate and the tubular furnace in step S11 depends on an annealing temperature: when the annealing temperature is 1000-1150° C., quartz material is selected, and when the annealing temperature is 1150-1350° C., corundum material is selected.

In some embodiments, the radial size of the single-crystal graphite obtained is 1-10 cm, and the longitudinal thickness is 0.01˜50 μm.

In an embodiment, the present disclosure provides a method for preparing a single-crystal nickel foil, the method comprising the following steps:
(1) placing a polycrystalline nickel foil on a high-temperature resistant substrate, placing them in a tubular furnace, and pre-oxidizing at 150-600° C. for 1-5 h;
(2) introducing an inert protective gas into the tubular furnace, and then heating to 1000-1350° C. within 60-120 minutes;
(3) maintaining at 1000-1350° C. for 1-20 h to anneal the nickel foil; and
(4) after the annealing, maintaining the atmosphere condition unchanged and cooling the system to room temperature to obtain the single-crystal nickel foil, wherein the inert protective gas is a mixture of Ar and H₂, and the volume ratio of Ar to H₂ is from 10:1 to 100:1, and the flow rates of Ar gas and H₂ gas are 100-1000 sccm and 5-200 sccm, respectively.

In the method of the present disclosure, through pre-oxidation treatment, the grains of the polycrystalline nickel foil grow abnormally under the induction of interface energy and surface energy, and finally a large-size single-crystal nickel foil is obtained. It should be noted that the size of the single-crystal nickel foil produced by the above method is related to the size of high-temperature annealing. At the same time, this method is not only suitable for nickel, but also can be extended to other metals.

In an embodiment, the present disclosure provides a method for growing a single-crystal graphite through solid-state transmission, the method comprising the steps of:
S1, providing a single-crystal nickel foil having a first surface and a second surface; and
S2, using the single-crystal nickel foil as a substrate, placing it on a solid carbon source, wherein the first surface of the single-crystal nickel foil is positioned close to the solid carbon source, while the second surface of the single-crystal nickel foil is positioned away from the solid carbon source, and finally growing high-quality single-crystal graphite on the second surface of the single-crystal nickel foil;
wherein step S2 specifically includes the following steps:
S21, placing the single-crystal nickel foil on the solid carbon source, and then placing them in the tubular furnace;
S22, introducing a mixture of argon and hydrogen into the tubular furnace, and then heating to 1000-1350° C. within 60-120 minutes, wherein the flow rates of argon and hydrogen in the mixture are 100-1000 sccm and 5-200 sccm, respectively;
S23, after the temperature rises to 1000-1350° C., maintaining for 10 min-50 h to allow the continuous epitaxy of graphite; and
S24, after the growth is completed, maintaining the atmosphere unchanged and cooling naturally to room temperature to obtain the single-crystal graphite.

In the present disclosure, a single-crystal nickel foil prepared by high-temperature annealing is placed on a solid carbon source, and single-crystal graphite is produced by absorbing carbon at high temperature and being driven by chemical potential gradient. The method proposed in the present disclosure solves the problem of difficulty in preparing a single-crystal graphite. It uses solid-state diffusion transmission of carbon and is not a vapor deposition method, and a large-sized single-crystal graphite with a length and width of 1 to 10 cm and a thickness of 0.1 to 50 μm can be obtained.

In an embodiment, the radial size of a graphite paper is larger than that of a nickel foil, and the radial size of the single-crystal graphite prepared is substantially the same as that of the single-crystal nickel foil, wherein the radial direction is a plane direction perpendicular to the thickness direction of graphite paper, nickel foil or graphite. The ratio of the radial size of the graphite paper to the radial size of the nickel foil can be from 2:1 to 50:1.

The foil substrate underlying the carbon film of the present disclosure can be removed by conventional methods. For example, a fresh ferric chloride solution is prepared, the prepared carbon film sample is placed in the solution and left to stand for 1 hour to 5 days, during which the ferric chloride reacts with nickel or copper-nickel alloy to etch away the foil; and then the obtained sample is placed into deionized water and rinsed several times to finally obtain the transferred carbon film sample.

The carbon film of the present disclosure can also be used to obtain a graphene film through a mechanical peeling method: specifically, sticking a tape on the prepared single-crystal graphite, tearing the tape off, sticking the tape to any substrate, heating it appropriately, and then removing the tape to obtain the graphene sample on the substrate after peeling. Because the quality of the prepared single-crystal graphite is very high, the quality of the sample peeled off is very pure, consistent with intrinsic graphene.

Advantages of the present disclosure include one or more of the following:
1. the method of the present disclosure is continuous growth of carbon film, wherein the carbon films include but are not limited to single-crystal graphite;
2. the present disclosure uses commercially available nickel foil, copper-nickel alloy foil and a variety of solid carbon sources as raw materials, and large-sized carbon films can be prepared without complex surface pretreatment of foils and carbon sources, and without introducing a carbon-containing atmosphere (methane, ethylene, acetylene, etc.), greatly reducing preparation costs;
3. the present disclosure provides a method for preparing single-crystal graphite which has large size, few defects, and superior performance, and has good application prospects; and
4. the method of the present disclosure is simple, effective and low-cost, and is helpful for the practical application and industrial production of large-sized single-crystal graphite.

The present disclosure will be further described in detail below with reference to specific examples, but the present disclosure is not limited to the following examples.

### EXAMPLE

Starting materials for the examples are commercially available and/or can be prepared in a variety of methods well known to those skilled in the material art.

### Examples 1-3: Preparation of Single-Crystal Nickel Foil

### Example 1

A single-crystal nickel foil was prepared in Example 1, including the following steps:
(1) a polycrystalline nickel foil (Alfa Aesar, thickness 100 μm, purity 99.99%) was placed on a high-temperature resistant corundum substrate, and they were placed in a tubular furnace (Tianjin Kaiheng Electric Heating Technology Co., Ltd.) to carry out pre-oxidation at 150° C. for 2 hours;
(2) an inert protective gas (Ar gas: 500 sccm; H₂: 50 sccm) was introduced into the tubular furnace, and then the temperature was raised to 1300° C. within 100 minutes;
(3) the temperature was maintained at 1300° C. for 8 h to anneal the nickel foil; and
(4) after the annealing, the atmosphere condition was maintained unchanged and the temperature began to be lowered, naturally cooling to room temperature.

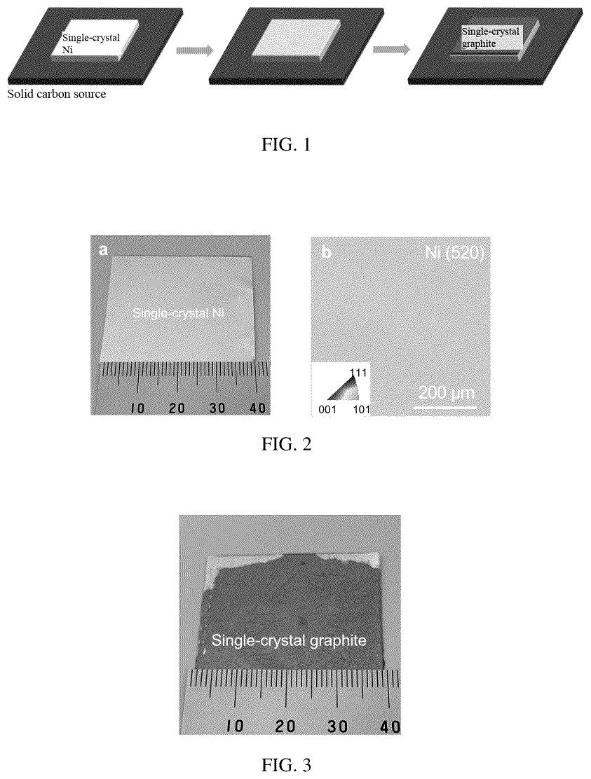

FIG. 2 showed the optical photo and electron back-scattered diffraction (EBSD) characterization result of the single-crystal nickel foil prepared in Example 1. The size of the nickel was 4*3 cm², and the EBSD result showed that it was a single crystal with a crystal plane index of (520). The electron back-scattered diffraction test in this disclosure used a PHI 710 Scanning Auger Nanoprobe system, and the test process was carried out according to standard protocol.

### Example 2

A single-crystal nickel foil was prepared in Example 2, including the following steps:
(1) a polycrystalline nickel foil was placed on a high-temperature resistant quartz substrate, and they were placed in a tubular furnace to carry out pre-oxidation at 600° C. for 1 h;
(2) an inert protective gas (Ar gas: 1000 sccm; H₂: 10 sccm) was introduced into the tubular furnace, and then the temperature was raised to 1000° C. within 60 minutes;
(3) the temperature was maintained at 1000° C. for 20 h to anneal the nickel foil; and
(4) after the annealing, the atmosphere condition was maintained unchanged and the temperature began to be lowered, naturally cooling to room temperature.

### Example 3

A single-crystal nickel foil was prepared in Example 3, including the following steps:
(1) a polycrystalline nickel foil was placed on a high-temperature corundum substrate, and they were placed in a tubular furnace to carry out pre-oxidation at 150° C. for 5 h;
(2) an inert protective gas (Ar gas: 700 sccm; H₂: 50 sccm) was introduced into the tubular furnace, and then the temperature was raised to 1350° C. within 120 minutes;
(3) the temperature was maintained at 1350° C. for 1 h to anneal the nickel foil; and
(4) after the annealing, the atmosphere condition was maintained unchanged and the temperature began to be lowered, naturally cooling to room temperature.

Similar to Example 1, the single-crystal nickel foils prepared in Examples 2 and 3 were also characterized.

### Examples 4-10: Preparation of Single-Crystal Graphite Using the Single-Crystal Nickel Foils Obtained from Examples 1-3

### Example 4

A single-crystal graphite was grown using a single-crystal nickel foil in Example 4, including the following steps:
(1) the single-crystal nickel foil obtained from Example 1 was placed on graphite paper (Beijing Jinglong Special Carbon Technology Co., Ltd., thickness of 100 μm, purity of 99.9%), and then they were placed into a tubular furnace;
(2) a mixture of argon and hydrogen (Ar: 500 sccm, H₂: 10 sccm) was introduced into the tubular furnace, and then the temperature was raised to 1300° C. within 120 minutes;
(3) after the temperature was raised to 1300° C., it was maintained for 10 hours to carry out infiltration growth of graphite; and
(4) after the growth was completed, the introduced atmosphere was maintained unchanged, and the system was naturally cooled down to room temperature. The sample was taken out to obtain a single-crystal graphite sample.

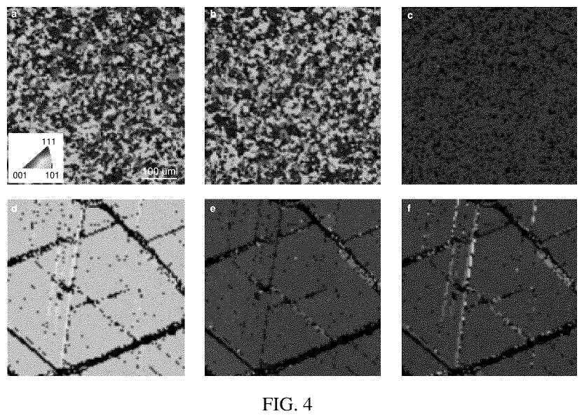

FIG. 3 was a photograph of the single-crystal graphite prepared in Example 4 of the present disclosure, in which the size of the prepared graphite was 4*3 cm².

FIG. 4 was an electron back-scattered diffraction pattern (EBSD) of highly oriented pyrolytic graphite (HOPG) and the single-crystal graphite prepared in Example 4 of the present disclosure. (a), (b) and (c) were EBSD patterns of highly oriented pyrolytic graphite in the x direction, y direction, and z direction respectively, indicating that although HOPG was a single crystal in the z direction, it had crystal plane rotation in the plane of x, y directions, and had poor single crystallinity. (d), (e) and (f) were EBSD patterns of the single-crystal graphite prepared in Example 4 of the present disclosure in the x direction, y direction, and z direction respectively, indicating that the graphite prepared in the present disclosure was single-crystal in the z direction, had no crystal plane rotation in the plane of x, y direction, and had good single crystallinity. The highly oriented pyrolytic graphite was from NT-MDT Company, and its purity was ZYA grade.

### Example 5

A single-crystal graphite was grown using a single-crystal nickel foil in Example 5, including the following steps:
(1) the single-crystal nickel foil obtained from Example 1 was placed on graphite powder (Alfa Aesar, 99%), and then they were placed into a tubular furnace;
(2) a mixture of argon and hydrogen (Ar: 500 sccm, H₂: 10 sccm) was introduced into the tubular furnace, and then the temperature was raised to 1300° C. within 120 minutes;
(3) after the temperature was raised to 1300° C., it was maintained for 10 hours to carry out infiltration growth of graphite; and
(4) after the growth was completed, the introduced atmosphere was maintained unchanged, and the system was naturally cooled down to room temperature. The sample was taken out to obtain a single-crystal graphite sample.

### Example 6

A single-crystal graphite was grown using a single-crystal nickel foil in Example 6, including the following steps:
(1) the single-crystal nickel foil obtained from Example 2 was placed on activated carbon (Ron Reagent), and then they were placed into a tubular furnace;
(2) a mixture of argon and hydrogen (Ar: 500 sccm, H₂: 10 sccm) was introduced into the tubular furnace, and then the temperature was raised to 1300° C. within 120 minutes;
(3) after the temperature was raised to 1300° C., it was maintained for 10 hours to carry out infiltration growth of graphite; and
(4) after the growth was completed, the introduced atmosphere was maintained unchanged, and the system was naturally cooled down to room temperature. The sample was taken out to obtain a single-crystal graphite sample.

### Example 7

A single-crystal graphite was grown using a single-crystal nickel foil in Example 7, including the following steps:
(1) the single-crystal nickel foil obtained from Example 2 was placed on carbon black (Ron Reagent), and then they were placed into a tubular furnace;
(2) a mixture of argon and hydrogen (Ar: 500 sccm, H₂: 10 sccm) was introduced into the tubular furnace, and then the temperature was raised to 1300° C. within 120 minutes;
(3) after the temperature was raised to 1300° C., it was maintained for 10 hours to carry out infiltration growth of graphite; and
(4) after the growth was completed, the introduced atmosphere was maintained unchanged, and the system was naturally cooled down to room temperature. The sample was taken out to obtain a single-crystal graphite sample.

### Example 8

A single-crystal graphite was grown using a single-crystal nickel foil in Example 8, including the following steps:
(1) the single-crystal nickel foil obtained from Example 3 was placed on graphite paper (Beijing Jinglong Special Carbon Technology Co., Ltd., thickness of 100 μm, purity of 99.9%), and then they were placed into a tubular furnace;
(2) a mixture of argon and hydrogen (Ar: 500 sccm, H₂: 5 sccm) was introduced into the tubular furnace, and then the temperature was raised to 1350° C. within 120 minutes;
(3) after the temperature was raised to 1350° C., it was maintained for 10 minutes to carry out infiltration growth of graphite; and
(4) after the growth was completed, the introduced atmosphere was maintained unchanged, and the system was naturally cooled down to room temperature. The sample was taken out to obtain a single-crystal graphite sample.

### Example 9

A single-crystal graphite was grown using a single-crystal nickel foil in Example 9, including the following steps:
(1) the single-crystal nickel foil obtained from Example 3 was placed on graphite paper (Beijing Jinglong Special Carbon Technology Co., Ltd., thickness of 100 μm, purity of 99.9%), and then they were placed into a tubular furnace;
(2) a mixture of argon and hydrogen (Ar: 1000 sccm, H₂: 10 sccm) was introduced into the tubular furnace, and then the temperature was raised to 1000° C. within 60 minutes;
(3) after the temperature was raised to 1000° C., it was maintained for 50 hours to carry out infiltration growth of graphite; and
(4) after the growth was completed, the introduced atmosphere was maintained unchanged, and the system was naturally cooled down to room temperature. The sample was taken out to obtain a single-crystal graphite sample.

### Example 10

A single-crystal graphite was grown using a single-crystal nickel foil in Example 10, including the following steps:
(1) the single-crystal nickel foil obtained from Example 3 was placed on graphite paper (Beijing Jinglong Special Carbon Technology Co., Ltd., thickness of 100 μm, purity of 99.9%), and then they were placed into a tubular furnace;
(2) a mixture of argon and hydrogen (Ar: 500 sccm, H₂: 100 sccm) was introduced into the tubular furnace, and then the temperature was raised to 1300° C. within 120 minutes;
(3) after the temperature was raised to 1300° C., it was maintained for 1 hour to carry out infiltration growth of graphite; and
(4) after the growth was completed, the introduced atmosphere was maintained unchanged, and the system was naturally cooled down to room temperature. The sample was taken out to obtain a single-crystal graphite sample.

Similar to Example 4, the single-crystal graphites prepared in Examples 5-10 were also confirmed by electron back-scattered diffraction.

Although the specific embodiments of the present invention have been described in detail, those skilled in the art will understand that various modifications and substitutions can be made to those details based on the above teachings disclosed, and these changes are all within the scope of the present disclosure. The scope of protection of the present disclosure is determined by the appended claims and their equivalents.

1. A method for continuous epitaxy of a carbon film, which comprises the following steps:
S1, providing a foil selected from a nickel foil or a copper-nickel alloy foil and having a first surface and a second surface; and
S2, using the foil as a substrate and placing it on a solid carbon source, wherein the first surface of the foil is positioned close to the solid carbon source, and the second surface of the foil is positioned away from the solid carbon source, and then heating the foil and the solid carbon source, thereby causing the carbon film to grow on the second surface of the foil through carbon diffusion.

2. The method according to claim 1, wherein the foil is a single-crystal nickel foil.

3. The method according to claim 1, wherein heating the foil and the solid carbon source is carried out in a tubular furnace.

4. The method according to claim 1, wherein heating the foil and the solid carbon source is carried out under a protective gas, and the protective gas is selected from one or more of argon gas, nitrogen gas, and hydrogen gas.

5. The method according to claim 4, wherein the protective gas is a mixture of argon gas and hydrogen gas.

6. The method according to claim 5, wherein the flow rates of argon gas and hydrogen gas in the mixture are 100-1000 sccm for Ar and 5-200 sccm for H₂ respectively.

7. The method according to claim 1, wherein heating the foil and the solid carbon source comprises the step of:
heating to a temperature of 900-1350° C. within 60-120 minutes and then maintaining at this temperature for 10 minutes to 50 hours.

8. The method according to claim 1, wherein after the growth is completed, the atmosphere is kept unchanged and the carbon film is naturally cooled down to room temperature.

9. The method according to claim 2, wherein step S1 includes the steps of:
S11, placing a polycrystalline nickel foil on a high-temperature resistant substrate, placing them in a tubular furnace, and pre-oxidizing at 150-650° C. for 1-5 h;
S12, introducing an inert protective gas into the tubular furnace, and then heating to 1000-1350° C. within 60-120 minutes;
S13, maintaining at 1000-1350° C. for 1-20 h to carry out an annealing process of the nickel foil; and
S14, after the annealing, maintaining the atmosphere condition unchanged and cooling the system to room temperature to obtain the single-crystal nickel foil.

10. The method according to claim 9, wherein steps S11-S14 are carried out in a tubular furnace.

11. The method according to claim 9, wherein the inert protective gas in step S12 is a mixture of Ar and H₂, and the volume ratio of Ar to H₂ is from 0.5:1 to 200:1.

12. The method according to claim 11, wherein the flow rates of Ar and H₂ in step S12 are 100-1000 sccm and 5-200 sccm, respectively.

13. The method according to claim 9, wherein in step S11, the high-temperature resistant substrate is a quartz or corundum substrate, and the tubular furnace is a quartz or corundum furnace.

14. The method according to claim 13, wherein selection of the high-temperature resistant substrate and the tubular furnace in step S11 depends on an annealing temperature: when the annealing temperature is 1000-1150° C., quartz material is selected, and when the annealing temperature is 1150-1350° C., corundum material is selected.

15. The method according to claim 1, wherein the solid carbon source is selected from one or more of graphite paper, graphite powder, activated carbon and carbon black.

16. The method according to claim 2, wherein the carbon film obtained is single-crystal graphite or graphene.

17. The method according to claim 16, wherein the carbon film obtained is single-crystal graphite, with a radial size of 1 to 10 cm and a longitudinal thickness of 0.1 to 50 μm.

18. The method according to claim 17, wherein the single-crystal graphite obtained has a consistent orientation.

19. The method according to claim 2, wherein the single crystal nickel foil has a crystal plane index of 520.

20. The method according to claim 19, wherein the carbon film obtained is single crystal graphite, with a radial size of 1 to 10 cm and a longitudinal thickness of 0.1 to 50 μm.
